(19) United States
(12) Patent Application Publication
(10) Pub. No.: US 2006/0285944 A1
(43) Pub. Date: Dec. 21, 2006

(54) FOUP loading load lock

(75) Inventor: Morgan Evans, Manchester, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 11/157,528

(22) Filed: Jun. 21, 2005

(51) Int. Cl. H01L 21/677

(52) U.S. Cl. 414/217

(57) ABSTRACT

A load lock system includes a load lock housing defining a load lock chamber, a substrate carrier platform configured to support a substrate carrier adjacent to the load lock housing, the substrate carrier having a substrate carrier door, and a load lock door to seal the load lock chamber. According to one aspect, the load lock system includes an attachment mechanism to secure the substrate carrier door to the load lock door and a door translation mechanism to move the load lock door and the substrate carrier door to and between an open position and a closed position. According to another aspect, the load lock system includes a load lock robot, located in the load lock chamber, to transfer a batch of substrates to and between the substrate carrier and the load lock chamber. The load lock robot includes a substrate pick which is configured to hold the batch of substrates in the load lock chamber for transfer to and from a process chamber.

### FIELD OF THE INVENTION

This invention relates to vacuum processing of substrates, such as semiconductor wafers, and, more particularly, to load lock systems for transferring substrates between a substrate carrier and a vacuum chamber.

### BACKGROUND OF THE INVENTION

The processing of substrates, such as semiconductor wafers, for the manufacture of microelectronic circuits involves processing tools for performing a large number of processing steps. The processing steps are usually performed in a vacuum chamber. The processing tools typically handle and process wafers one at a time in order to optimize control and reproduceability. Such processing tools utilize automated wafer handling systems.

The throughput of the processing tools is an important factor in achieving low cost manufacture. The overall throughput is a function of both the processing time and the efficiency of automated wafer handling. Wafer handling involves introduction of the wafers in a wafer carrier into the processing tool, transfer of the wafers from the wafer carrier to a processing station, return of the wafers to the wafer carrier following processing, and removal of the wafer carrier from the processing tool. Wafer processing is performed in a vacuum chamber.

Wafer handling systems usually include one or more load locks for transferring wafers to and from the vacuum chamber with little impact on the pressure level in the vacuum chamber. The wafer carrier may be a FOUP (Front Opening Unified Pod), which is a standardized wafer carrier utilized for transporting wafers in fabrication facilities. The FOUP encloses the wafers and limits the risk of contamination. In some applications, cassette wafer carriers are utilized. Some of the processing and wafer handling operations may be performed concurrently to achieve efficient operation and high throughput. Accordingly, careful design of wafer handling systems is required. A variety of wafer handling techniques are known in the prior art.

In one prior art system, a pair of robot arms located in a vacuum chamber transfers wafers from a load lock to an alignment station and then to a processing station. A buffer is utilized to transfer wafers from several FOUP's to the load locks. The buffer includes a robot in a controlled environment buffer chamber for transferring wafers to and between the FOUP's and the load locks. The prior art wafer handling system has the capability of processing wafers from multiple FOUP's. However, the system including the buffer is large, complex and expensive. In some applications, the complexity of the buffer is not required.

In another prior art system disclosed in U.S. Pat. No. 5,486,080, issued Jan. 23, 1996 to Sieradzki, a buffer is not utilized and cassette wafer carriers are placed directly in first and second load locks. A pair of robot arms located in a vacuum chamber transfers wafers from a first cassette in the first load lock to an alignment station and then to a processing station. After wafers from the first cassette have been processed, the robots reverse their respective roles and begin processing wafers from a second cassette located in the second load lock, while the first load lock is vented and the first cassette is replaced with a new cassette.

In another prior art system disclosed in U.S. Pat. No. 6,364,592, issued Apr. 2, 2002 to Hofmeister, a buffer is not utilized and a loader module including a robot arm is positioned between the FOUP's and the load locks.

U.S. Pat. No. 6,120,229, issued Sep. 19, 2000 to Hofmeister, discloses a wafer batchloading system wherein a substrate carrier is moved into a load lock for loading and unloading of wafers. This arrangement produces particulate contamination of the load lock and requires a relatively large volume load lock.

All of the known prior art wafer handling systems have had one or more drawbacks, including but not limited to relatively low throughput, large space requirements, high cost and complex design. Accordingly, there is a need for improved methods and apparatus for transferring substrates, such as semiconductor wafers, between a substrate carrier and a vacuum chamber.

### SUMMARY OF THE INVENTION

According to a first aspect of the invention, a load lock system comprises a load lock housing defining a load lock chamber, a substrate carrier platform configured to support a substrate carrier adjacent to the load lock housing, the substrate carrier having a substrate carrier door, a load lock door to seal the load lock chamber, an attachment mechanism to secure the substrate carrier door to the load lock door, a door translation mechanism to move the load lock door and the substrate carrier door to and between an open position and a closed position, and a controller to control operation of the attachment mechanism and the door translation mechanism.

The attachment mechanism may be located in the load lock door. The substrate carrier platform may include a substrate carrier mechanism to move the substrate carrier between a load/unload position and a retracted position.

The controller may be programmed to move the substrate carrier to the load/unload position, to secure the substrate carrier door to the load lock door, to move the substrate carrier to the retracted position, to move the load lock door and the substrate carrier door to the open position, and to move the substrate carrier to the load/unload position, whereby substrates in the substrate carrier are available for unloading to the load lock chamber.

The load lock system may further comprise an environmental structure defining a controlled environment between the load lock and the substrate carrier. The environmental structure may comprise an enclosure between the load lock and the substrate carrier, and an airflow unit to direct a flow of clean air through the enclosure.

According to a second aspect of the invention, a load lock system comprises a load lock housing defining a load lock chamber, a substrate carrier platform configured to support a substrate carrier adjacent to the load lock housing, the substrate carrier having a substrate carrier door, a load lock robot, located in the load lock chamber, to transfer a batch of substrates to and between the substrate carrier and the load lock chamber, and a controller to control operation of the load lock robot.

The load lock robot may comprise a substrate pick to support the batch of substrates, an elevator to raise and lower the substrate pick, and a translation mechanism to move the substrate pick to and between the load lock chamber and the substrate carrier. The substrate pick may be configured to hold the batch of substrates in the load lock chamber for transfer of the substrates, one at a time, to and from a process chamber.

The controller may be programmed to move the substrate pick into the substrate carrier, to raise the substrate pick to lift the substrates in the substrate carrier, and to move the substrate pick carrying the substrates from the substrate carrier to the load lock chamber. The controller may be programmed to index the substrate pick upwardly and downwardly in the load lock chamber for transfer of substrates to a process chamber.

### BRIEF DESCRIPTION OF THE DRAWINGS

For a better understanding of the present invention, reference is made to the accompanying drawings, which are incorporated herein by reference and in which:

FIG. 1 is a schematic top view of a wafer handling system in accordance with an embodiment of the invention;

FIG. 2 is a schematic side view of a load lock system in the wafer handling system of FIG. 1;

FIGS. 3A and 3B illustrate an embodiment of a wafer pick utilized in the wafer handling system of FIG. 1;

FIGS. 4A and 4B show a flow chart of an embodiment of a process for operation of the load lock system of FIG. 2;

FIG. 5 shows a flow chart of an embodiment of a process for moving wafers from the wafer carrier to the load lock; and

FIGS. 6-11 are schematic diagrams of the load lock system in various stages of operation.

### DETAILED DESCRIPTION

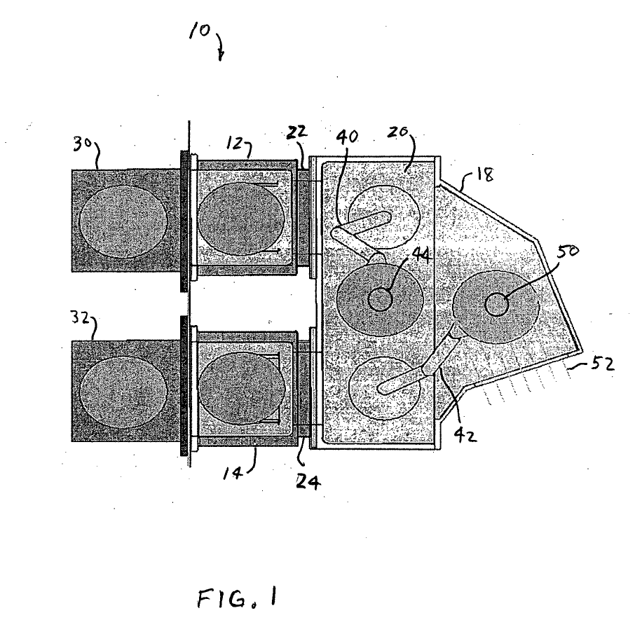

A top view of a substrate handling system in accordance with an embodiment of the invention is shown in FIG. 1. The system is described as a system for handling semiconductor wafers. However, it will be understood that the system can be utilized to handle other types of substrates, such as for example flat panel displays.

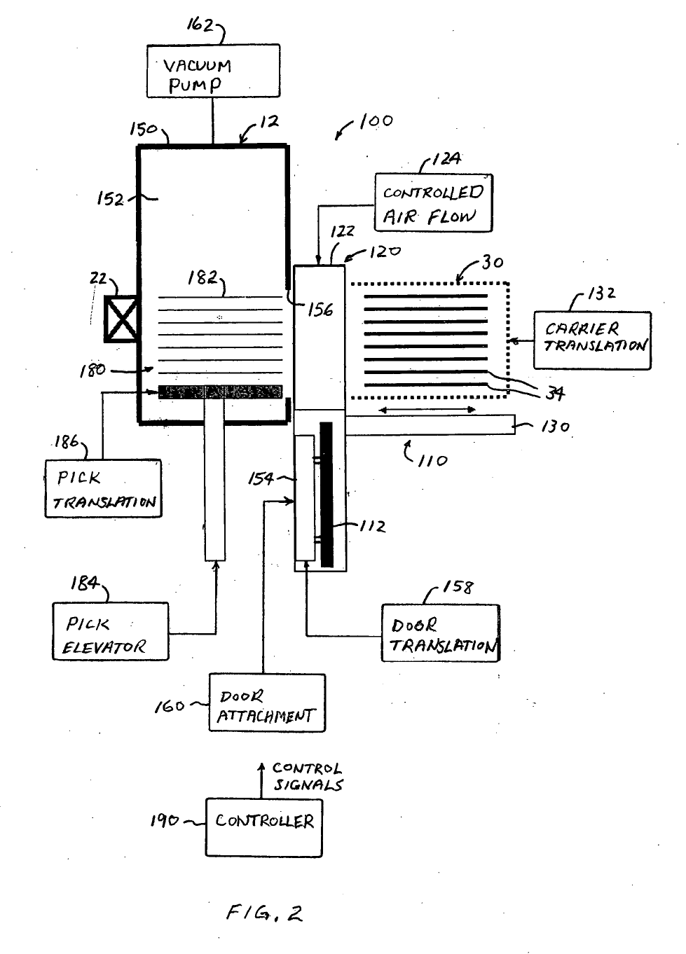

A wafer handling system 10 includes load locks 12 and 14, a vacuum-tight housing 18 that encloses a wafer handling chamber 20, and isolation valves 22 and 24. Isolation valve 22 is mounted between load lock 12 and wafer handling chamber 20, and isolation valve 24 is mounted between load lock 14 and wafer handling chamber 20. Wafer carriers 30 and 32 are mounted on substrate carrier platforms (FIG. 2) to permit access from load locks 12 and 14, respectively. Wafer carriers 30 and 32 may be FOUPs that enclose wafers 34.

A first vacuum robot 40, a second vacuum robot 42, an alignment station 44 and a processing station 50 may be located in wafer handling chamber 20. A vacuum pumping system (not shown) maintains a desired pressure level in wafer handling chamber 20. In one embodiment, wafer handling system 10 is utilized in an ion implantation system. An ion beam 52 supplied by an ion beam generator (not shown) is incident on a wafer at the processing station 50. However, wafer handling system 10 is not limited to ion implantation applications.

In operation, a batch of wafers is transferred from wafer carrier 30 to load lock 12, as described below. Then, load lock 12 is vacuum pumped to a pressure near the pressure in chamber 20, and isolation valve 22 is opened. First vacuum robot 40 removes a first wafer from load lock 12 and places it at alignment station 44. After alignment, second vacuum robot 42 transfers the first wafer from alignment station 44 to processing station 50. During this time, first vacuum robot 40 returns to load lock 12, removes a second wafer and transfers the second wafer to alignment station 44. After the first wafer has been processed at processing station 50, first vacuum robot 40 removes the processed first wafer from processing station 50 and returns it to load lock 12. At the same time, second vacuum robot 42 moves the second wafer from alignment station 44 to processing station 50. This sequence continues until all the wafers in load lock 12 have been processed. Subsequently, the wafers in load lock 14 are processed in a similar manner, with the operations of vacuum robots 40 and 42 reversed.

A schematic side view of load lock 12 and wafer carrier 30 is shown in FIG. 2. Load lock 14 and wafer carrier 32 of FIG. 1 may have the same configuration.

A load lock system 100 incorporating load lock 12 may include a wafer carrier platform 110 for receiving and mounting wafer carrier 30. Wafer carrier 30 includes a wafer carrier door 112, shown in an open position in FIG. 2. Wafer carrier 30 may be a standardized carrier, such as a FOUP, that is configured to enclose wafers 34 during transport in the fabrication facility and to limit the risk of wafer contamination. However, other wafer carriers and carriers for other types of substrates may be utilized within the scope of the invention.

An environmental structure 120 is positioned between load lock 12 and wafer carrier 30. Environmental structure 120 establishes a controlled environment between load lock 12 and wafer carrier 30 to limit the risk of wafer contamination during loading and unloading of wafers from wafer carrier 30. Environmental structure 120 may include an enclosure 122 positioned between load lock 12 and wafer carrier 30 and having openings to load lock 12 and wafer carrier 30. Enclosure 122 may have sufficient volume to enclose wafer carrier door 112 and load lock door 154 in the open position. A controlled airflow unit 124 directs a flow of clean air downwardly through enclosure 122.

Wafer carrier platform 110 includes a wafer carrier support 130 and a carrier translation mechanism 132. Wafer carrier support 130 may include pins or other locating devices for positioning wafer carrier 30 on platform 110. Translation mechanism 132 moves wafer carrier 30 between a retracted position and a load/unload position. In the retracted position, wafer carrier 30 can be removed from platform 110. Translation mechanism 132 moves wafer carrier 30 from the retracted position toward load lock 12 to the load/unload position. In the load/unload position, wafers can be loaded into or unloaded from wafer carrier 30 if the wafer carrier door 112 is open.

Load lock 12 includes a load lock housing 150, which defines a load lock chamber 152, and a load lock door 154. Load lock housing 150 is provided with an opening 156 that permits loading and unloading of wafers from wafer carrier 30. Load lock door 154 is movable between an open position shown in FIG. 2 and a closed position covering and sealing opening 156. A door translation mechanism 158 controls movement of load lock door 154 between the open and closed positions. A door attachment mechanism 160 located in load lock door 154 unlocks wafer carrier door 112 and secures wafer carrier door 112 to load lock door 154. The attached doors 112 and 154 can be moved between open and closed positions by door translation mechanism 158. A vacuum pump 162 is connected to load lock housing 150 for vacuum pumping of load lock chamber 152 when load lock door 154 is in the closed position.

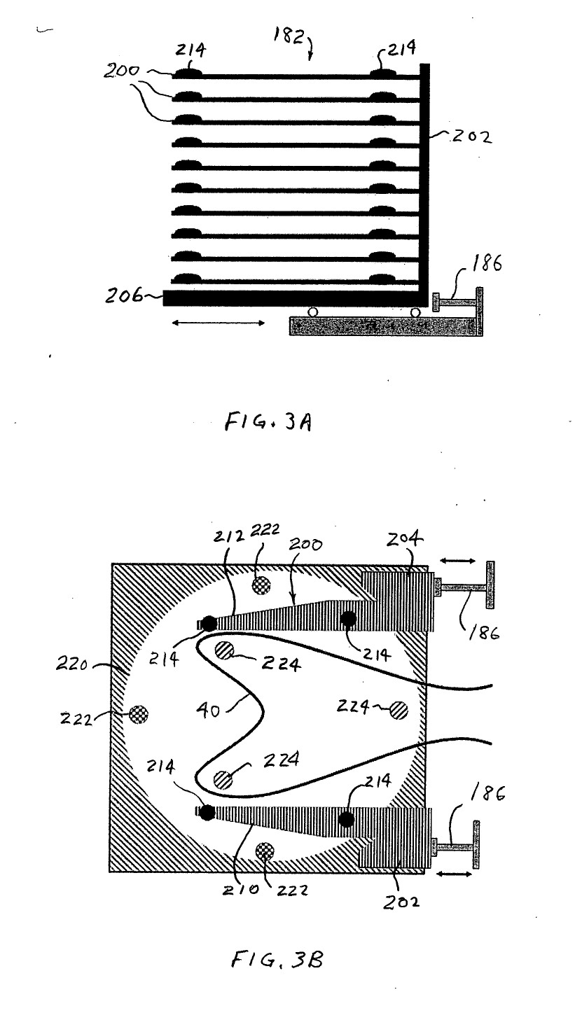

Load lock 12 further includes a load lock robot 180 that is located within load lock chamber 152. Load lock robot 180 includes a wafer pick 182, a pick elevator 184 and a pick translation mechanism 186. Load lock robot 180 is configured to move a batch of wafers, typically all the wafers in wafer carrier 30, from wafer carrier 30 to load lock chamber 152 for transfer to wafer handling chamber 20 (FIG. 1) and to move the batch of wafers from load lock chamber 152 to wafer carrier 30 after processing. Wafer pick 182 of load lock robot 180 serves as a wafer holder during transfer of wafers to and from wafer handling chamber 20. Wafer pick 182 is shown in greater detail in FIGS. 3A and 3B and is described below.

A controller 190 controls carrier translation mechanism 132, door translation mechanism 158, door attachment mechanism 160, pick elevator 184, pick translation mechanism 186, vacuum pump 162, isolation valves 22 and 24 (FIG. 1) and vacuum robots 40 and 42, for operation as described below. Controller 190 may be a general purpose computer, such as a PC, a microcontroller or a special purpose controller.

A schematic side view of wafer pick 182 is shown in FIG. 3A, and a schematic top view of wafer pick 182 is shown in FIG. 3B, in accordance with an embodiment of the invention. Wafer pick 182 may include a plurality of pick hands 200 extending from support posts 202 and 204, which in turn are affixed to a base 206. The number of pick hands 200 may correspond to the number of wafer locations in wafer carrier 30. While fewer pick hands 200 are shown in FIG. 3A, wafer pick 182 may include 25 pick hands 200, in an embodiment of the invention, for operation with FOUPs.

As shown in FIG. 3B, each pick hand 200 may include fingers 210 and 212 that extend horizontally from support posts 202 and 204, respectively. Fingers 210 and 212 may be thin metal strips, for example. Pick hands 200 further include wafer contacts 214 mounted to fingers 210 and 212. Wafer contacts 214 define points of contact with semiconductor wafers as they are being handled by the load lock system. In the embodiment of FIGS. 3A and 3B, each finger has two contacts 214. The spacing between pick hands 200 matches the spacing between wafers in wafer carrier 30, thereby permitting pick hands 200 to move into substrate carrier 30 between adjacent wafers. Wafer pick 182 may be moved horizontally into and out of substrate carrier 30 by operation of pick translation mechanism 186.

Wafer pick 182 is configured to access the wafers in substrate carrier 30, to support wafers in load lock chamber 152 and to permit access to the wafers by vacuum robot 40. The points of contact with a wafer 220 are shown schematically in FIG. 3B. Wafer 220 is supported in wafer carrier 30 at contact points 222. Wafer 220 is supported by wafer pick 182 at wafer contacts 214. Wafer 220 is supported by vacuum robot 40 at contact points 224. Thus, wafer pick 182 may extend into substrate carrier 30 to access wafers without interfering with contact points 222. Similarly, vacuum robot 40 may extend into load lock chamber 152 to access wafers held by wafer pick 182 without interfering with contact points 214. It will be understood that FIG. 3B is schematic in nature to illustrate the points where wafer 220 is contacted. In practice, vacuum robot 40 does not extend into substrate carrier 30 during operation of the load lock system.

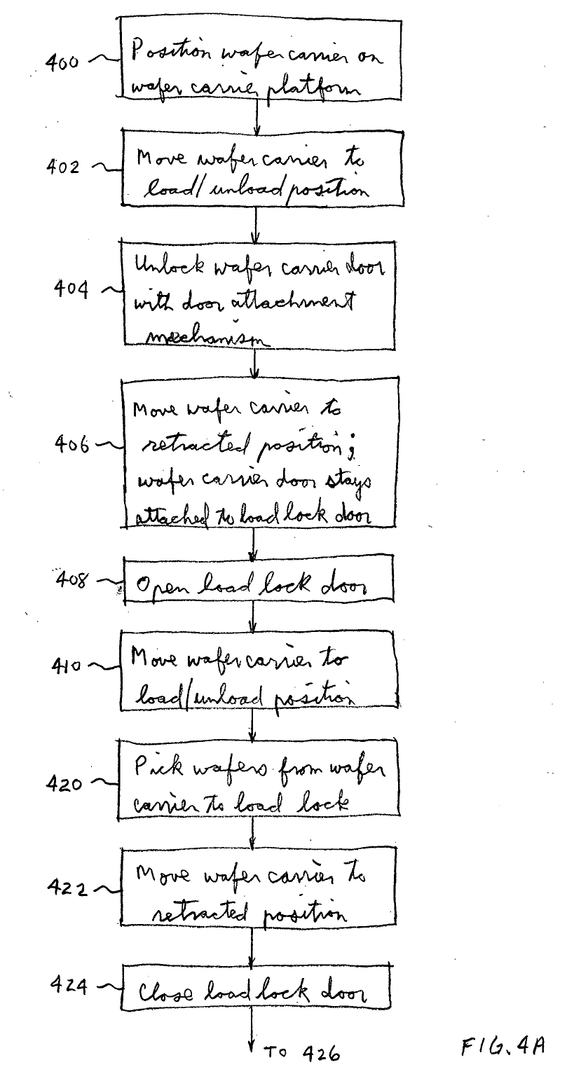

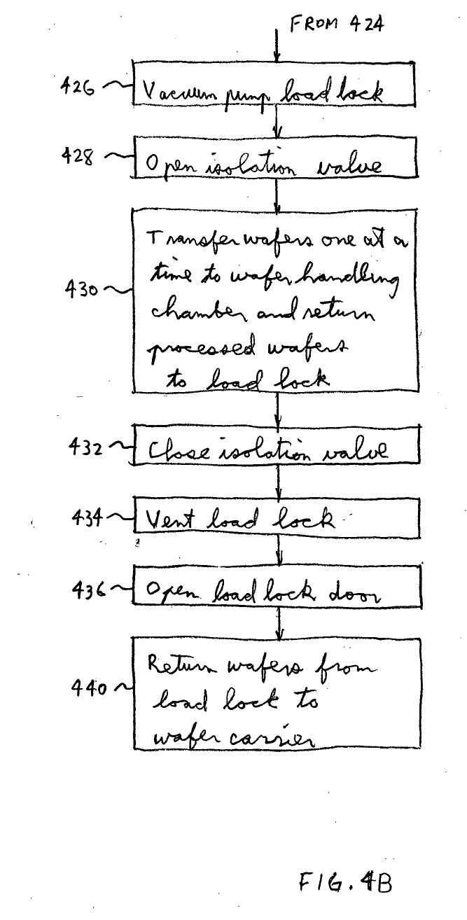

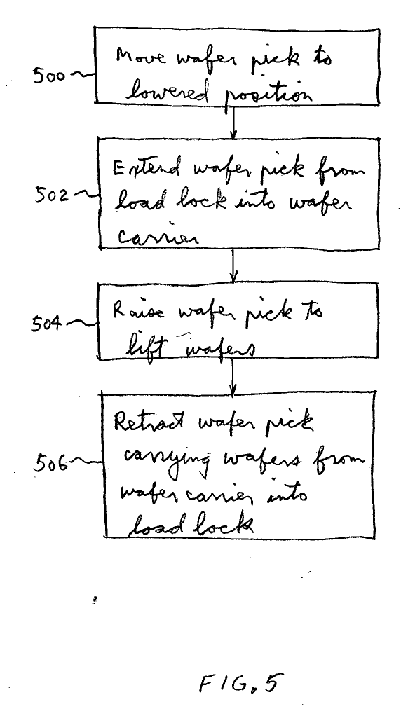

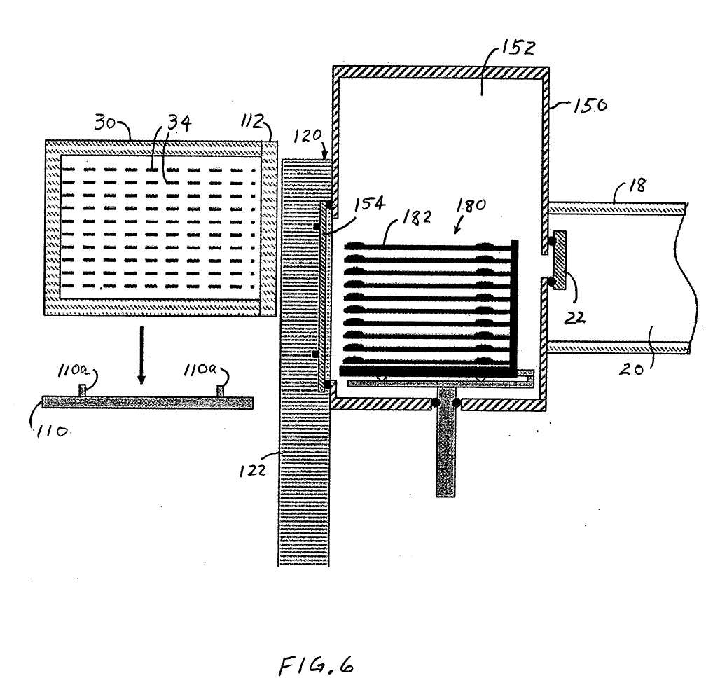

A flow chart of an embodiment of a process for operation of the load lock system of FIG. 2 is shown in FIGS. 4A and 4B. Schematic diagrams of the load lock system at various stages of operation are shown in FIGS. 6-11. As is apparent, FIGS. 6-11 are reversed from left to right with respect to FIG. 2.

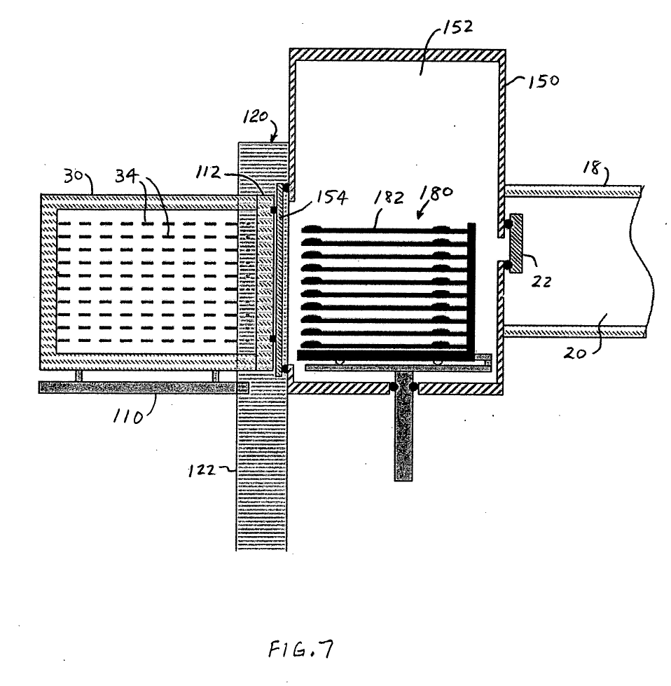

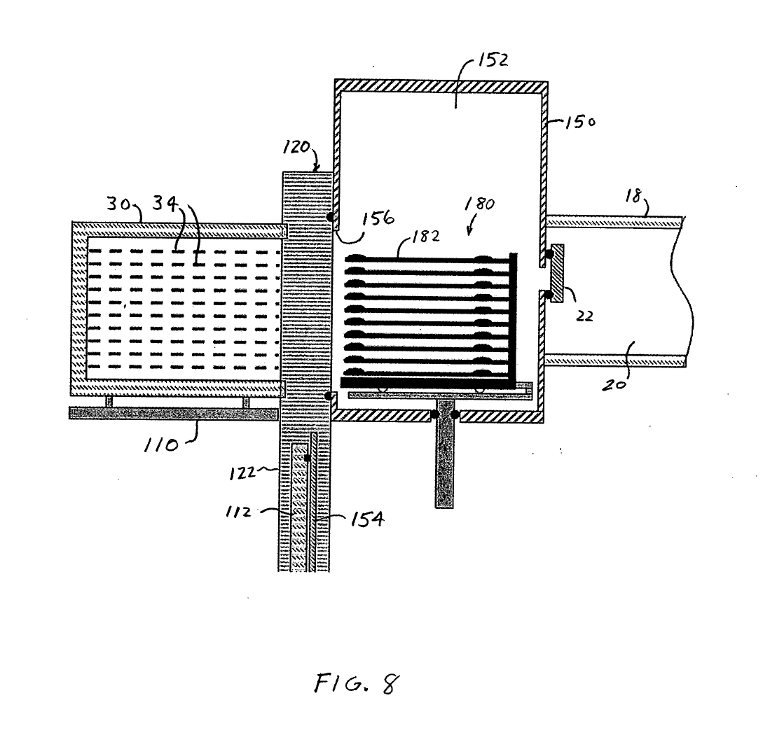

In step 400, a wafer carrier, such as wafer carrier 30, is positioned on wafer carrier platform 110, as shown in FIG. 6. The positioning of wafer carrier 30 may be manual or automated, depending on the operation of the fabrication facility. The wafer carrier is positioned in the retracted position and may be located on wafer carrier platform 110 by pins 110a or other locating devices. In step 402, wafer carrier 30 is moved from the retracted position toward load lock 12 to the load/unload position, as shown in FIG. 7, by operation of carrier translation mechanism 132. In the load/unload position, wafer carrier door 112 is in close proximity to load lock door 154.

In step 404, door attachment mechanism 160 of load lock door 154 engages wafer carrier door 112, as shown in FIG. 7. More particularly, door attachment mechanism 160 unlocks wafer carrier door 112 so that it can be removed from wafer carrier 30 and secures wafer carrier door 112 to load lock door 154. It will be understood that a variety of different mechanisms can be utilized to secure wafer carrier door 112 to load lock door 154. Mechanisms for opening doors of wafer carriers are disclosed by way of example in U.S. Pat. No. 6,244,812, issued Jun. 12, 2001 to Patterson et al.; U.S. Pat. No. 6,382,896, issued May 7, 2002 to Hu et al.; U.S. Pat. No. 6,837,663, issued Jan. 4, 2005 to Mages et al.; and U.S. Pat. No. 6,869,263, issued Mar. 22, 2005 to Gilchrist.

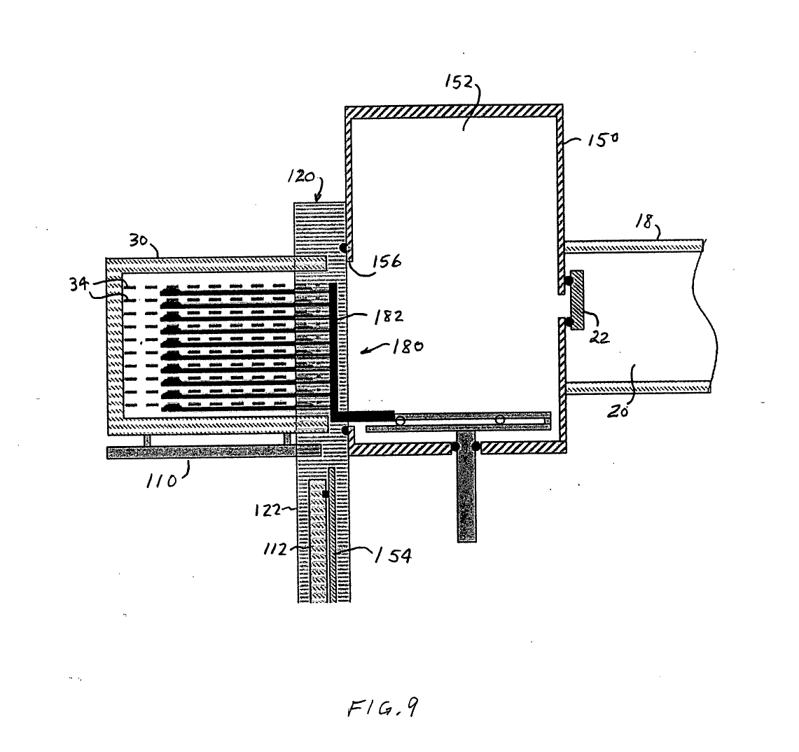

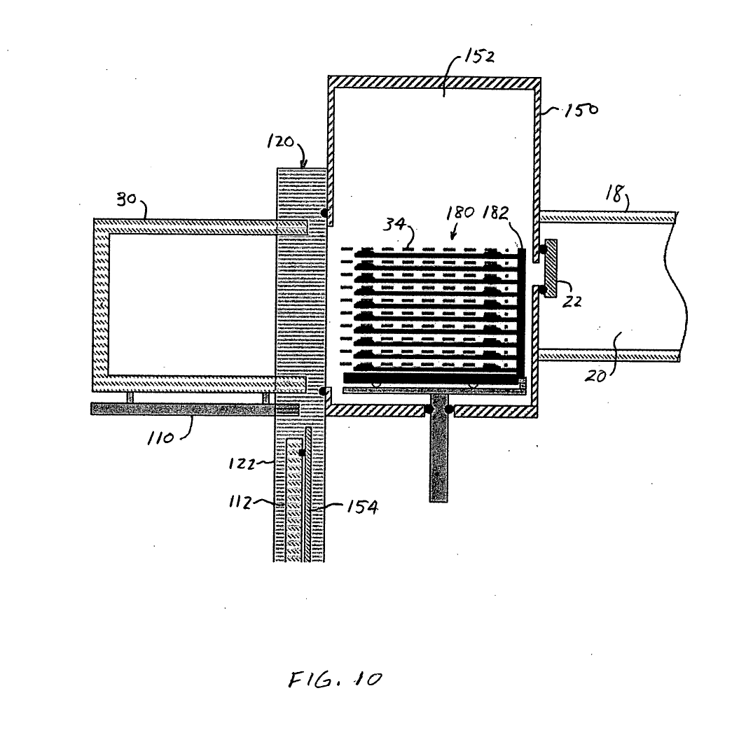

In step 406, wafer carrier 30 is moved to the retracted position by operation of carrier translation mechanism 132, and wafer carrier door 112 remains attached to load lock door 154. In step 408, load lock door 154 is moved from the closed position to the open position, as shown in FIG. 8. Wafer carrier door 112 is carried with load lock door 154 to the open position. In step 410, wafer carrier 30 is moved from the retracted position to the load/unload position in engagement with environmental structure 120, as shown in FIG. 9.

With load lock door 154 and wafer carrier door 112 in the open position, load lock robot 180 can access wafer carrier 30 through environmental structure 120. Environmental structure 120 provides a controlled environment in a region between load lock 12 and wafer carrier 30. In particular, load lock housing 150 abuts against one side of enclosure 122, and wafer carrier 30 abuts against an opposite side of enclosure 122. A flow of clean air through enclosure 122 limits the risk of wafer contamination during transfer of wafers between wafer carrier 30 and load lock 12.

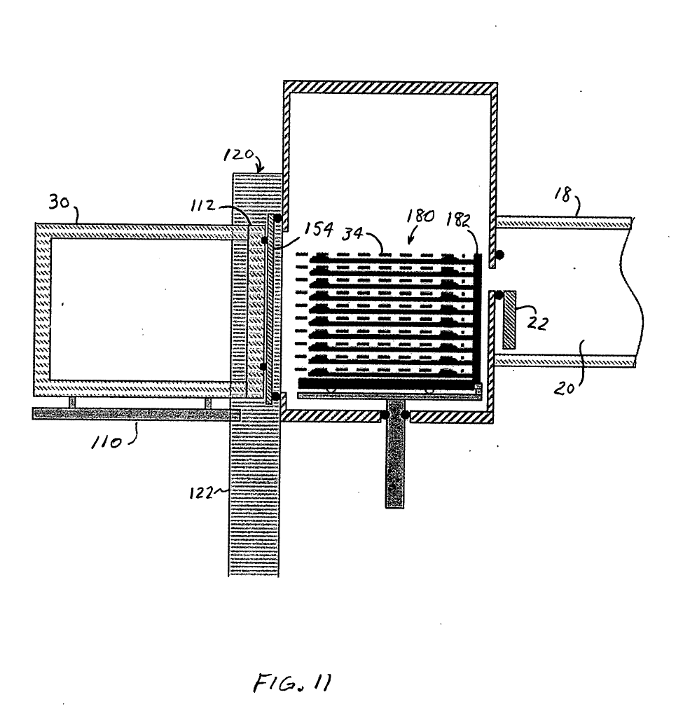

In step 420, a batch of wafers is transferred from wafer carrier 30 to load lock chamber 152 by operation of load lock robot 180, as shown in FIGS. 9 and 10. In particular, wafer pick 182 is configured to simultaneously transfer a batch of wafers, typically all the wafers in wafer carrier 30. A FOUP typically carries a maximum of 25 wafers.

The wafer transfer of step 420 is shown in detail in the flow chart of FIG. 5. In step 500, wafer pick 182 is moved to a lowered position by operation of elevator 184. The lowered position of wafer pick 182 is selected such that the individual wafer supports of wafer pick 182 can enter wafer carrier 30 between adjacent wafers. In step 502, wafer pick 182 is extended from load lock chamber 152 into wafer carrier 30 by operation of translation mechanism 186. The individual wafer supports of wafer pick 182 move into wafer carrier 30 between adjacent wafers, as shown in FIG. 9. In step 504, wafer pick 182 is raised by operation of elevator 184 so that the wafers in wafer carrier 30 are lifted from their supports in wafer carrier 30 and are supported by wafer pick 182. In step 506, wafer pick 182 carrying the batch of wafers is retracted from wafer carrier 30 and is moved into load lock chamber 152 by operation of translation mechanism 186, as shown in FIG. 10. It will be understood that wafer pick 182 can carry one or more wafers at a time.

Referring again to FIG. 4A, in step 422 wafer carrier 30 is moved to the retracted position after the wafers have been removed from wafer carrier 30 and transferred to load lock chamber 152. In step 424, load lock door 154 is closed by operation of door translation mechanism 158, as shown in FIG. 11. In step 426 (FIG. 4B), load lock chamber 152 is vacuum pumped by operation of vacuum pump 162 to a pressure level at or near the pressure in wafer handling chamber 20. In step 428, isolation valve 22 is opened, as shown in FIG. 11, to permit access to load lock chamber 152 by vacuum robot 40 (FIG. 1).

In step 430, the wafers in load lock chamber 152 are transferred one at a time to wafer handling chamber 20 for processing. The processing may involve ion implantation of the wafers, for example. The processed wafers are returned to load lock chamber 152 following processing. During this phase of the operation, wafer pick 182 serves as a wafer holder in load lock chamber 152. Elevator 184 indexes wafer pick 182 upwardly and downwardly to permit vacuum robot 40 to access a desired wafer. In particular, wafer pick 182 is moved by elevator 184 to a level slightly above vacuum robot 40. Then, vacuum robot 40 enters load lock chamber 152 below the desired wafer, as shown in FIG. 3B, and the wafer is transferred to vacuum robot 40 by raising robot 40 or lowering wafer pick 182. The wafer is then removed from load lock chamber 152 by vacuum robot 40. Wafers are returned to wafer pick 182 by performing the above steps in reverse order. Preferably, wafers are returned to the same position in wafer pick 182 after processing.

After all wafers in the batch have been processed, isolation valve 22 is closed in step 432. In step 434, load lock chamber 152 is vented to atmosphere, and load lock door 154 is opened in step 436. Wafer carrier door 112 remains attached to load lock door 154 at this stage. In step 440, the batch of wafers held by substrate pick 182 is returned from load lock chamber 152 to wafer carrier 30. In returning the batch of wafers to wafer carrier 30, the steps used to remove wafers are performed in reverse order.

Thus, wafer pick 182 is part of load lock robot 180 for purposes of transferring a batch of wafers from wafer carrier 30 to load lock 12 and for transferring a batch of wafers from load lock 12 to wafer carrier 30. For purposes of transferring wafers, one at a time, to and from wafer handling chamber 20, wafer pick 182 serves as a wafer holder, or cassette, in load lock chamber 152.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A load lock system comprising:
a load lock housing defining a load lock chamber;
a substrate carrier platform configured to support a substrate carrier adjacent to the load lock housing, the substrate carrier having a substrate carrier door;
a load lock door to seal the load lock chamber;
an attachment mechanism to secure the substrate carrier door to the load lock door;
a door translation mechanism to move the load lock door and the substrate carrier door to and between an open position and a closed position; and
a controller to control operation of the attachment mechanism and the door translation mechanism.

2. A load lock system as defined in claim 1, further comprising an environmental structure defining a controlled environment between the load lock and the substrate carrier.

3. A load lock system as defined in claim 2, wherein the environmental structure comprises an enclosure between the load lock and the substrate carrier, and an airflow unit to direct a flow of clean air through the enclosure.

4. A load lock system as defined in claim 1, wherein the attachment mechanism is located in the load lock door.

5. A load lock system as defined in claim 1, wherein the substrate carrier platform includes a substrate carrier mechanism to move the substrate carrier between a load/unload position and a retracted position.

6. A load lock system as defined in claim 5, wherein the controller is programmed to move the substrate carrier to the load/unload position, to secure the substrate carrier door to the load lock door, to move the substrate carrier to the retracted position, to move the load lock door and the substrate carrier door to the open position, and to move the substrate carrier to the load/unload position, whereby substrates in the substrate carrier are available for unloading to the load lock chamber.

7. A load lock system as defined in claim 1, further comprising a load lock robot to transfer a batch of substrates to and between the substrate carrier and the load lock chamber, wherein the load lock robot is located in the load lock chamber.

8. A load lock system as defined in claim 7, wherein the load lock robot comprises a substrate pick to support the batch of substrates, an elevator to raise and lower the substrate pick, and a translation mechanism to move the substrate pick to and between the load lock chamber and the substrate carrier.

9. A load lock system as defined in claim 8, wherein the substrate pick is configured to hold the batch of substrates in the load lock chamber.

10. A load lock system comprising:
a load lock housing defining a load lock chamber;
a substrate carrier platform configured to support a substrate carrier adjacent to the load lock housing, the substrate carrier having a substrate carrier door;
a load lock robot, located in the load lock chamber, to transfer a batch of substrates to and between the substrate carrier and the load lock chamber; and
a controller to control operation of the load lock robot.

11. A load lock system as defined in claim 10, wherein the load lock robot comprises a substrate pick to support the batch of substrates, an elevator to raise and lower the substrate pick, and a translation mechanism to move the substrate pick to and between the load lock chamber and the substrate carrier.

12. A load lock system as defined in claim 11, wherein the substrate pick is configured to hold the batch of substrates in the load lock chamber for transfer to and from a process chamber.

13. A load lock system as defined in claim 12, wherein the substrate pick is configured for transfer of substrates to and from the process chamber one at a time.

14. A load lock system as defined in claim 11, wherein the controller is programmed to move the substrate pick into the substrate carrier, to raise the substrate pick to lift the substrates in the substrate carrier, and to move the substrate pick carrying the substrates from the substrate carrier to the load lock chamber.

15. A load lock system as defined in claim 14, wherein the controller is further programmed to index the substrate pick upwardly and downwardly in the load lock chamber for transfer of substrates to a process chamber.

16. A load lock system as defined in claim 10, further comprising an environmental structure defining a controlled environment between the load lock chamber and the substrate carrier.

17. A load lock system as defined in claim 16, further comprising a load lock door to seal the load lock chamber, an attachment mechanism to secure the substrate carrier door to the load lock door, and a door translation mechanism to move the load lock door and the substrate carrier door to and between an open position and a closed position.

18. A load lock system as defined in claim 17, wherein the substrate carrier platform includes a substrate carrier mechanism to move the substrate carrier between a load/unload position and a retracted position.
